(19) United States
(12) Patent Application Publication
(10) Pub. No.: US 2011/0042702 A1
(43) Pub. Date: Feb. 24, 2011

(54) Organic Light Emitting Device and Method for Manufacturing the Same

(76) Inventors: Hyuk LIM, Seoul (KR); Hyung Sup Lee, Suwon-si (KR); Young Sam Yu, Seoul (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/854,089

(22) Filed: Aug. 10, 2010

(30) Foreign Application Priority Data
Aug. 19, 2009 (KR) 10-2009-0076808

(51) Int. Cl. H01L 33/52; H01L 33/00

(52) U.S. Cl. 257/98; 438/29; 257/E33.059; 257/E33.001

(57) ABSTRACT

Provided are an organic light emitting device and a method for manufacturing the same. The organic light emitting device includes: a substrate; an organic light emitting device layer on the substrate; an encapsulation layer on the organic light emitting device, the encapsulation layer comprising at least one first layer and at least one second layer on the first layer, the first layer having a different refractive index from the second layer; and a moisture transmission layer on the encapsulation layer, the moisture transmission layer being configured to prevent moisture from permeating the encapsulation layer. The encapsulation layer is formed by stacking material layers having different refractive indexes to protect the organic light emitting device layer. Thus, light emitted to lateral surfaces of the organic light emitting device which is a surface emitting device can be directed toward a front surface to improve optical radiation efficiency.

### CROSS-REFERENCE TO RELATED APPLICATION

This application claims priority to Korean Patent Application No. 10-2009-0076808 filed on Aug. 19, 2009 and all the benefits accruing therefrom under 35 U.S.C. §119, the contents of which are incorporated by reference in their entirety.

### BACKGROUND

The present disclosure relates to an organic light emitting device and a method for manufacturing the same, and more particularly, to an organic light emitting device capable of improving an encapsulation function of a device and increasing optical radiation efficiency and a method for manufacturing the same.

An organic light emitting diode (OLED) is one of self-luminous devices. A light emitting surface of such OLED may include interfaces having different refractive indexes, which results in unnecessary reflection, absorption, scattering, and refraction on the light emitting surface, and thereby leads to deterioration of optical radiation efficiency. For example, in case of a backlit OLED, a large amount of light emitted from an emitting layer is lost by reflection, absorption, scattering, etc., due to a difference of refractive indexes between the emitting layer and a substrate, and between the substrate and atmosphere. Thus, only a portion of the light is actually emitted through the light emitting surface.

The OLED is a surface emitting device. Thus, a large amount of light emitted from the OLED is substantially lost through lateral surfaces of the light emitting surface. That is, the large amount of the light emitted from the emitting layer of the OLED is emitted through side portions (i.e., the lateral surfaces) of the emitting layer.

To suppress leakage of light through the lateral surfaces of the OLED, a fine lens shape is attached to the substrate. Alternatively, two or more organic materials having similar refractive indexes are manufactured to have an appropriate geometric structure. However, the above ways still have drawbacks since manufacturing process of such structures is complicated and not cost effective.

### SUMMARY

The present disclosure provides an organic light emitting device capable of increasing optical radiation efficiency by staking material layers having a large refractive index difference, and improving encapsulation performance of a device by an encapsulation layer having a stacked structure, as well as simplifying a manufacturing process and reducing manufacturing costs, and a method for manufacturing the same.

In accordance with an exemplary embodiment, an organic light emitting device includes: a substrate; an organic light emitting device layer on the substrate; an encapsulation layer on the organic light emitting device, the encapsulation layer comprising at least one first layer and at least one second layer on the first layer, the first layer having a different refractive index from the second layer; and a moisture transmission layer on the encapsulation layer, the moisture transmission layer being configured to prevent moisture from permeating the encapsulation layer.

The at least one first layer has a first refractive index and the at least one second layer has a second refractive index, wherein the second refractive index is from approximately one and a half times to four times greater than the first refractive index.

The first refractive index may be from approximately 1.4 to approximately 2.2, and the second refractive index may be from approximately 3.5 to approximately 4.5.

Each of the first and second layers of the encapsulation layer may include a silicon-based material that is deposited using a plasma-enhanced chemical vapor deposition (PECVD) process.

The first layer may include a SiOx layer, a SiON layer, a SiNx layer, or a combination thereof and the second layer may include a Si layer containing hydrogen atom.

The second layer may be between a plurality of stacked first layers. The first layer and the second layer may include a stack in which the second layer is on the first layer

The first layer may have a thickness of from approximately 100 nm to approximately 10,000 nm, and the second layer may have a thickness of from approximately 1 nm to approximately 90 nm.

The first layer and the second layer have different interfacial characteristics.

In accordance with another exemplary embodiment, a method of manufacturing an organic light emitting device includes: forming an organic light emitting device layer on a substrate; and forming an encapsulation layer in which at least two layers having different refractive indexes are stacked on the substrate.

Forming the encapsulation layer may include: forming a first protection layer including a first SiOx layer, a first SiON layer, a first SiNx layer, or a first combination thereof on the substrate; and forming a second protection layer including a Si layer on the first protection layer, wherein each of the first and second protection layers may be formed at a temperature of approximately 300° C. or less using a PECVD process.

The method may further include forming a third protection layer including a second SiOx layer, a second SiON layer, a second SiNx layer, or a second combination thereof on the second protection layer. The method may further include preparing the substrate

### BRIEF DESCRIPTION OF THE DRAWINGS

Exemplary embodiments can be understood in more detail from the following description taken in conjunction with the accompanying drawings, in which:

FIGS. 1 through 3 are sectional views illustrating a method for manufacturing an organic light emitting device in accordance with an exemplary embodiment;

FIG. 4 is an enlarged sectional view illustrating a region A of FIG. 2 for explaining characteristics of an insulating paste material; and

FIG. 5 is a sectional view for explaining a method for forming a insulating layer.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, like reference numerals refer to like elements throughout.

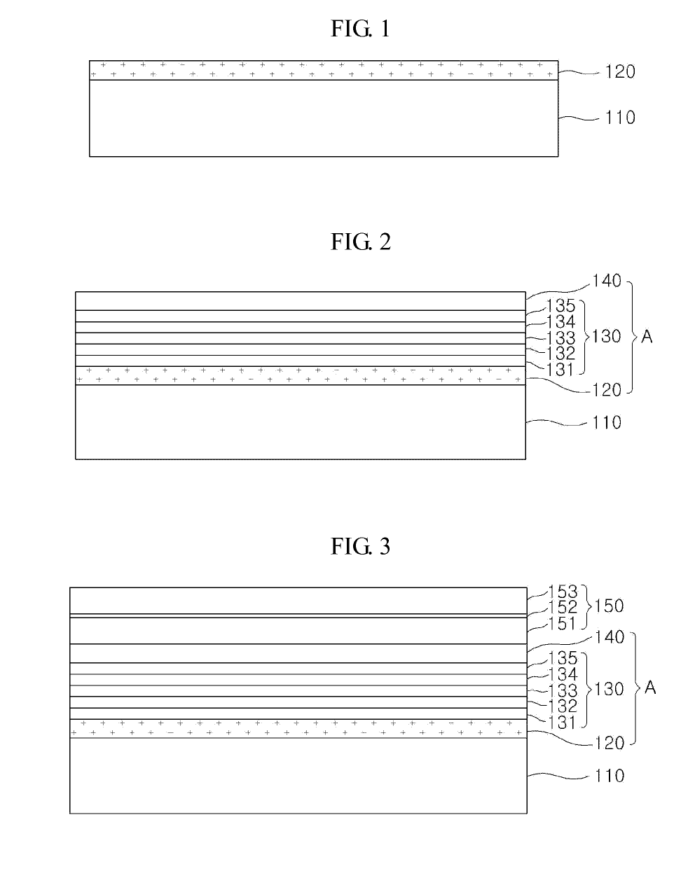

FIGS. 1 through 3 are sectional views illustrating a method for manufacturing an organic light emitting device in accordance with an exemplary embodiment.

To manufacture an organic light emitting device in accordance with an exemplary embodiment, firstly, a lower electrode 120 is formed on a substrate 110 as illustrated in FIG. 1.

Here, a glass or plastic substrate may be used as the substrate 110. However, the present invention is not limited thereto. For example, a transparent thin silicon or sapphire substrate may be used as the substrate 110. In the present exemplary embodiment, the transparent glass substrate is used as the substrate 110.

A conductive layer is formed on the substrate 110 to form the lower electrode 120. The conductive layer is patterned (i.e., etched using a mask) to form the lower electrode 120. Here, various material layers may be used as the conductive layer in accordance with light emitting characteristics of a device. For example, in a case of a top-emission light emitting device, the conductive layer may be formed of a metal material. Here, a metallic material having a superior reflectance may be used as the metal material. Also, in a case of a transparent device, the conductive layer may be formed of a transparent conductive material.

The conductive layer may be formed of one of Al, Au, Pd, Pt, Rh, Ru, Ir, Ag, Cu, alloys thereof, and combinations thereof or one of ITO, IZO, ZnO, SnO, and In₂O₃. Also, the conductive layer may be patterned through an etch process using a photoresist mask or a scribing process using laser. However, the present invention is not limited thereto. For example, when a deposition process is performed, the lower electrode 120 having a desired pattern may be formed using a layer such as a shadow mask. As described above, a insulating layer surrounding a lateral region of the lower electrode 120 may be further formed after the lower electrode 120 is formed.

Referring to FIG. 2, an organic light emitting layer 130 is formed on the lower electrode 120. Then, an upper electrode 140 is formed on the organic light emitting layer 130 to form an organic light emitting device layer A.

For this, a hole injection layer (HIL) 131, a hole transport layer (HTL) 132, an emitting layer (EML) 133, an electron transport layer (ETL) 134, and an electron injection layer (EIL) 135 are sequentially formed on the substrate 110 to form the organic light emitting layer 130.

That is, an organic layer such as CuPc or MTDATA is formed on the lower electrode 120 to form the HIL 131. AN organic layer such as NPB or TPD is formed on the HIL 131 to form the HTL 132. The EML 133 is formed on the HTL 132. Here, the EML 133 may include one of a green light emitting layer formed of Alq₃ or Alq₃:C545T, a red light emitting layer formed of Alq₃:DCJTB, a blue light emitting layer formed of SAlq or DPVBi, and combinations thereof. A material layer formed of Alq₃ is formed on the EML 133 to form the ETL 134. A material layer formed of LiF or BCP:Cs is formed on the ETL 134 to form the EIL 135. Here, the material constituting each layer is not limited to the above-described materials. For example, various material layers that are developed in recent may be used. Also, at least one layer of the five layers may be omitted according to a structure and characteristic of the device. If required, a layer having a different structure may be inserted. The respective layers may be formed as a single layer or a multi-layer.

As described above, the organic light emitting layer 130 is formed on the substrate 110, and then, the upper electrode 140 is formed on the organic light emitting layer 130.

For this, a conductive layer used as the upper electrode 140 is deposited on the organic light emitting layer 130. Here, a transparent conductive layer having transparency of approximately 50% or more may be used as the conductive layer. Thus, one of ITO, IZO, ZnO, SnO, and In₂O₃ may be used as the upper electrode 140.

Here, the transparent conductive layer may be deposited on the substrate 110, and then, the patterning process may be performed to form the upper electrode 140. The patterning process may be performed through the etch process using the photoresist mask. However, the present invention is not limited thereto. For example, when the deposition process is performed, the upper electrode 140 having a desired pattern may be formed using a layer such as a shadow mask.

Referring to FIG. 3, an encapsulation layer 150 for protecting the organic light emitting device layer A is formed. Here, a plurality of protection layers 151, 152, and 153 having a large refractive index difference may be stacked to form the encapsulation layer 150. That is, a first layer having a first refractive index and a second layer having a second refractive index, which are alternately stacked on each other may be used as the encapsulation layer 150. Here, the stacked number of the first and second layers may be variously varied according to light emitting efficiency of the device. It may be effective that the protection layers stacked adjacent to each other have different refractive indexes.

In the present exemplary embodiment, the first through third protection layers 151, 152, and 153 are sequentially stacked to form the encapsulation layer 150 as illustrated in FIG. 3.

Here, it is effective that one protection layer of the first through third protection layers 151, 152, and 153 has a refractive index approximately one and half times to four times greater than the other protection layer. In this regard, light refraction may occur on an interface between the protection layers due to a difference between the refractive indexes of the protection layers. As a result, a total reflection angle may be decreased on the interface (i.e., an interface between different media) between the two layers. Thus, diffusion and diffused reflection of the light may be suppressed in a region between the media. In the present exemplary embodiment, light emitted toward a lateral surface of the organic light emitting device may be directed upward due to the difference of the refractive indexes. Also, diffused reflection of light within the media may be suppressed to improve the light emitting efficiency of the device.

When a refractive index difference is less than the foregoing range, an amount of upwardly emitting light is reduced to deteriorate the light emitting efficiency. Also, when a refractive index difference is greater than the foregoing range, light is significantly refracted between the protection layers. As a result, the laterally emitting light is concentrated in a center direction of an upper side of the device to cause non-uniform light emission, or the upwardly emitting light is significantly refracted and emitted in a lateral direction of the device to deteriorate the light emitting efficiency of the device.

Here, the protection layers 151, 152, and 153 constituting the encapsulation layer 150 should be deposited at a low temperature, because the organic light emitting layer 130 below the protection layers 151, 152, and 153 may be easily deteriorated by heat. Thus, the protection layers 151, 152, and 153 should be formed at a low temperature of approximately 300° C. or less. To meet the above conditions, an organic material layer or an inorganic material layer that can be deposited at a low temperature may be used as the encapsulation layer 150. Alternatively, the organic material layer and the inorganic material layer deposited at the lower temperature may be stacked to form the encapsulation layer 150.

In the present exemplary embodiment, the inorganic material layer deposited at the low temperature is used as the first through third protection layers 151, 152, and 153. In order to deposit the inorganic material layer at low temperature, a chemical vapor deposition process (e.g., plasma-enhanced chemical vapor deposition (PECVD) process) or a sputtering process may be performed.

In the present exemplary embodiment, a layer including silicon may be used as the first through third protection layers 151, 152, and 153. Also, it may be effective that the second protection layer 152 has a refractive index greater than those of the first and third protection layers 151 and 153. Here, it may be effective that the first and third protection layers 151 and 153 have the same refractive index or similar to each other (within approximately ±20% range). The first layer having the first refractive index and the second layer having the second refractive index are sequentially stacked, and the second layers are disposed between the first layers. Therefore, the light emitting efficiency of the device may be improved.

Thus, an insulation layer containing silicon is used as the first and third protection layers 151 and 153. That is, a SiOₓ layer, a SiON layer, a SiNₓ layer or a combination thereof is used as the first and third protection layers 151 and 153. A Si layer is used as the second protection layer 152.

The insulating layer containing the silicon has a refractive index of from approximately 1.4 to approximately 2.2. On the other hand, the Si layer used as the second protection layer 152 may have a refractive index of from approximately 3.5 to approximately 4.5. Here, the refractive index of the Si layer may be adjusted within the foregoing range according to its deposition condition. At this time, it is effective that the Si layer is deposited using the PECVD process. As a result, when the deposition condition is changed or a reaction gas is added during the PECVD process, the refractive index of the Si layer is changed. Thus, the refractive index of the second protection layer 152 may be adjusted within the foregoing range. For example, the deposition condition and the reaction gas may be adjusted to adjust a residual amount of hydrogen atoms within the Si layer, thereby changing the refractive index of the Si layer.

Also, the first and third protection layers 151 and 153 may be manufactured using the PECVD process. That is, it represents that the first through third protection layers 151, 152, and 153 may be manufactured using an in-situ process within a single deposition apparatus.

Thus, the substrate 110 including the organic light emitting device layer A is loaded into a PECVD chamber. Then, a silicon source material and an insulating material (i.e., an oxygen-containing material and/or a nitrogen containing material) are supplied into the chamber to form the first protection layer 151 (e.g., the SiOₓ layer) along a surface profile of the substrate 110 including the organic light emitting device layer A. Sequentially, the supply of the insulating material is intercepted or a small amount (only approximately 2% to approximately 10% of the pre-process) of the insulating material is supplied. Also, the silicon source material is continuously supplied to form the second protection layer 152 (e.g., the Si layer) on the first protection layer 151. Then, the insulating material is supplied again to form the third protection layer 153 (e.g., the SiOₓ layer) on the second protection layer 152. As a result, the encapsulation layer 150 having a SiOₓ layer/Si layer/SiOₓ layer structure.

However, the present invention is not limited thereto. For example, when the third protection layer 153 is formed, a source material different from the insulating material for depositing the first protection layer 151 may be supplied into the PECVD chamber. Thus, the third protection layer 153 (e.g., the SiNₓ layer or the SiON layer) different from the first protection layer 151 may be formed. This way, the encapsulation layer 150 may have a SiOₓ layer/Si layer/SiNₓ layer structure or a SiOₓ layer/Si layer/SiONₓ layer structure. Alternately, material of the first protection layer 151 and material of the third protection layer 153 may be swapped with each other.

As described above, since the three layers are sequentially deposited using the PECVD process, the defect of the thin film due to the low-temperature deposition may be minimized.

That is, since the first through third protection layers 151, 152, and 153 are deposited under the low temperature, a plurality of defects or pinholes exists in each of the protection layers. The defects or pinholes are continuously generated in a defect region where they are once formed, and the defects are not removed even though the thin film gets thicker. However, as described in the exemplary embodiment, since materials having surface energies different from each other are stacked and deposited, it may prevent defects from occurring again in the region in which the defects exist. Accordingly, it may prevent the defects from being three-dimensionally formed, and thus, the encapsulation effect of the encapsulation layer 150 may be improved.

A surface energy represents an energy of a surface of a material. Thus, two material layers having different surface energies have different interface characteristic or surface characteristic. The surface energy may be varied according to surface conditions of the material. Different materials have different surface energies even though the surface conditions are similar to each other.

Here, the SiOₓ layer, the SiON layer, and the SiNₓ layer, which are used as the first and third protection layers 151 and 153 have superior light transmittance. However, since the hydrogenated Si layer (i.e., hydrogen-containing Si layer) used as the second protection layer 152 has a color, the Si layer has light transmittance less than those of the first and third protection layers 151 and 153. Thus, in the present exemplary embodiment, the second protection layer 152 has a thickness thinner than those of the first and third protection layers 151 and 153. That is, the second protection layer 152 has a thickness of from approximately 1 nm to approximately 90 nm in which the light transmittance is not reduced. It is effective that the first and third protection layers 151 and 153 are deposited with a thickness of from approximately 100 nm to approximately 10,000 nm to improve the encapsulation effect. In the present exemplary embodiment, the first layer (i.e., the first and third protection layers 151 and 153) having the first refractive index and the second protection layer (i.e., the second protection layer 152) having the second refractive index may be stacked several times. Thus, the thickness of the respective thin films may be varied according to the stacked number of the thin films and the target thickness of the whole encapsulation layer 150.

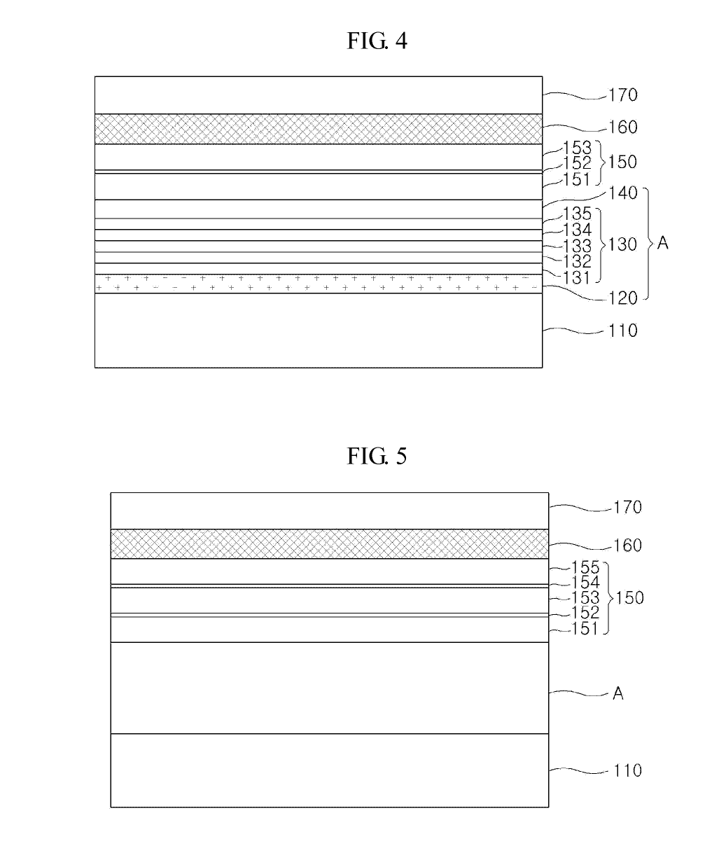

Referring to FIG. 4, a moisture transmission layer 160 is disposed on the encapsulation layer 150. A cover 170 is coupled to the substrate 110 including the moisture transmission layer 160 to form the organic light emitting device.

Here, the moisture transmission layer 160 refers to a layer capable of preventing moisture from being permeated. As described above, the encapsulation layer 150 in accordance with the exemplary embodiment prevents the diffuse reflection from occurring due to the refractive index difference of the light, but is not resistant to moisture permeation. Thus, the moisture transmission layer 160 is disposed on the encapsulation layer 150 to prevent the organic light emitting layer 130 disposed below the encapsulation layer 150 from being damaged by the moisture permeation. Here, since the encapsulation layer 150 is disposed below (i.e., between the moisture transmission layer 160 and the organic light emitting layer 130) the moisture transmission layer 160, the transmittance of light emitted from the organic light emitting layer 130 may be improved. When the moisture transmission layer 160 is disposed directly on the organic light emitting layer 130 and the encapsulation layer 150 in accordance with the exemplary embodiment is disposed on the moisture transmission layer 160, a large amount of light is diffusely reflected by the inside of the moisture transmission layer 160 and the interfaces (i.e., the interface between the moisture transmission layer 160 and the organic light emitting layer 130 and the interface between the moisture transmission layer 160 and the encapsulation layer 150) to deteriorate the light emitting efficiency.

Thus, in the present exemplary embodiment, the moisture transmission layer 160 is disposed on the encapsulation layer 150 to improve the light emitting efficiency and prevent the organic layers from being deteriorated by the moisture permeation. Here, it is effective that the moisture transmission layer 160 has a moisture transmission characteristic of approximately 10⁻¹⁰⁰ g/m²/day (or cc/m²/day) to approximately 10⁻³ g/m²/day (or cc/m²/day). Also, one of CaO and BaO may be used as the moisture transmission layer 160 in accordance with the present exemplary embodiment.

Also, in the present exemplary embodiment, the cover 170 may be further disposed on the moisture transmission layer 160. Here, it is effective to use a transparent insulating layer as the cover 170. Alternatively, a cap-shaped plate capable of preventing moisture from being permeated may be used as the cover 170. In the present exemplary embodiment, a glass or transparent plastic plate is used as the cover 170. Thus, the glass plate covers an upper region of the substrate 110 to protect the organic light emitting device layer A.

The present invention is not limited to the foregoing description, and the encapsulation layer 150 may include first through fifth protection layers 151, 152, 153, 154, and 155 as a modified embodiment illustrated in FIG. 5. Here, it is effective that the second and fourth protection layers 152 and 154 have refractive indexes greater than those of the first, third, and fifth protection layers 151, 153, and 155. As describe above, the layers having the different refractive indexes from each other may be stacked to improve the light emitting efficiency of the light emitted from the lateral surfaces of the device.

Also, an organic material layer, but the glass plate may be used as the cover 170. That is, the organic material layer may be disposed on the encapsulation layer 150 and thus used as the cover 170 that prevents the moisture and foreign substances from being permeated. Also, the cover 170 may be omitted.

The present disclosure is not limited to the exemplary embodiments described above, and can be applied to various surface emitting electro-optic devices including an encapsulation layer formed by stacking one or more layers having different refractive indexes.

As described above, the material layers having the different refractive indexes different may be stacked to form the encapsulation layer protecting the organic light emitting device layer. Thus, the light directed to the lateral surfaces of the organic light emitting device which is a surface emitting device may be emitted toward a front surface to improve the optical radiation efficiency.

Also, the encapsulation performance of the organic light emitting device layer may be improved through the encapsulation layer having the stacked structure, the manufacturing process can be simplified, and the manufacturing costs can be reduced.

Although the an organic light emitting device and a method for manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. An organic light emitting device comprising:
a substrate;
an organic light emitting device layer on the substrate;
an encapsulation layer on the organic light emitting device, the encapsulation layer comprising at least one first layer and at least one second layer on the first layer, the first layer having a different refractive index from the second layer; and
a moisture transmission layer on the encapsulation layer, the moisture transmission layer being configured to prevent moisture from permeating the encapsulation layer.

2. The organic light emitting device of claim 1, wherein the at least one first layer has a first refractive index and the at least one second layer has a second refractive index, wherein the second refractive index is from approximately one and a half times to four times greater than the first refractive index.

3. The organic light emitting device of claim 2, wherein the first refractive index is from approximately 1.4 to approximately 2.2.

4. The organic light emitting device of claim 3, wherein the second refractive index is from approximately 3.5 to approximately 4.5.

5. The organic light emitting device of claim 2, wherein the second refractive index is from approximately 3.5 to approximately 4.5.

6. The organic light emitting device of claim 1, wherein each of the first and second layers of the encapsulation layer comprises a silicon-based material that is deposited using a plasma-enhanced chemical vapor deposition (PECVD) process.

7. The organic light emitting device of claim 2, wherein the first layer comprises a SiOx layer, a SiON layer, a SiNx layer, or a combination thereof.

8. The organic light emitting device of claim 7, wherein the second layer comprises a Si layer containing hydrogen atoms.

9. The organic light emitting device of claim 2, wherein the second layer comprises a Si layer containing hydrogen atoms.

10. The organic light emitting device of claim 2, wherein the second layer is between a plurality of stacked first layers.

11. The organic light emitting device of claim 2, wherein the first layer and the second layer comprise a stack in which the second layer is on the first layer.

12. The organic light emitting device of claim 2, wherein the first layer has a thickness of from approximately 100 nm to approximately 10,000 nm.

13. The organic light emitting device of claim 12, wherein the second layer has a thickness of from approximately 1 nm to approximately 90 nm.

14. The organic light emitting device of claim 2, wherein the second layer has a thickness of from approximately 1 nm to approximately 90 nm.

15. The organic light emitting device of claim 1, wherein the first layer and the second layer have different interfacial characteristics.

16. A method of manufacturing an organic light emitting device, the method comprising:
forming an organic light emitting device layer on a substrate; and
forming an encapsulation layer in which at least two layers having different refractive indexes are stacked on the substrate.

17. The method of claim 16, wherein forming the encapsulation layer comprises:
forming a first protection layer comprising a first SiOx layer, a first SiON layer, a first SiNx layer, or a first combination thereof on the substrate; and
forming a second protection layer comprising a Si layer on the first protection layer,
wherein each of the first and second protection layers are formed at a temperature of approximately 300° C. or less using a PECVD process.

18. The method of claim 17, further comprising forming a third protection layer comprising a second SiOx layer, a second SiON layer, a second SiNx layer, or a second combination thereof on the second protection layer.

19. The method of claim 16, further comprising preparing the substrate;
